(19) United States
(12) Patent Application Publication
(10) Pub. No.: US 2026/0198200 A1
(43) Pub. Date: Jul. 9, 2026

(54) DISPLAY DEVICE AND ELECTRONIC DEVICE INCLUDING THE SAME

(71) Applicant: Samsung Display Co., Ltd., Yongin-Si (KR)

(72) Inventors: DONGJIN MOON, Yongin-si (KR); JUNSEOK MIN, Yongin-si (KR); KYUYOUNG CHOI, Yongin-si (KR)

(21) Appl. No.: 19/398,451

(22) Filed: Nov. 24, 2025

(30) Foreign Application Priority Data
Jan. 8, 2025 (KR) 10-2025-0002913

(51) Int. Cl. H10K 59/40; G06F 3/044; H10K 59/121; H10K 59/131; H10K 59/38; H10K 59/80; H10K 102/00

(52) U.S. Cl. CPC H10K 59/40; G06F 3/0446; H10K 59/1213; H10K 59/1315; H10K 59/38; H10K 59/8792; G06F 2203/04102; H10K 2102/311

(57) ABSTRACT

A display device including a display panel including a display area, a pad and a bending area between the display area and the pad area, and an input detection layer on the display panel, wherein the input detection layer includes a plurality of detection electrodes arranged in the display area, detection signal lines extending to the pad area across the bending area and having one ends respectively connected to the plurality of detection electrodes, an insulating layer located at least in the bending area and the pad area and covering at least a portion of the detection signal lines, and a step compensation layer located at least on the insulating layer in the bending area, the insulating layer includes a first groove extending parallel to a bending axis of the display panel and disposed outside the step compensation layer.

### CROSS-REFERENCE TO RELATED APPLICATION

This application is based on and claims priority under 35 U.S.C. § 119 to Korean Patent Application No. 10-2025-0002913, filed on Jan. 8, 2025, in the Korean Intellectual Property Office, the disclosure of which is incorporated by reference herein in its entirety.

### BACKGROUND

### 1. Field

The disclosure relates to a display device and an electronic device including the same.

### 2. Description of the Related Art

Recently, various types of lightweight and compact flat panel display devices have been developed. Flat panel display devices include liquid crystal displays (LCDs), field emission displays (FEDs), plasma display panels (PDPs), and organic light-emitting displays (OLEDs).

Among flat panel display devices, OLEDs display images by using organic light-emitting diodes that emit light through recombination of electrons and holes. These OLEDs are receiving attention as next-generation displays because they have fast response speeds and operate with low power consumption.

The aforementioned background technology is technical information possessed by the inventor for derivation of the disclosure or acquired by the inventor during the derivation of the disclosure, and is not necessarily prior art disclosed to the public before the application of the disclosure.

### SUMMARY

Provided are a display device having improved electrical characteristics and improved efficiency of manufacturing processes, and an electronic device including the display device.

Aspects of the disclosure are not limited to those mentioned above, and other aspects and advantages of the disclosure, which are not mentioned, will be understood from descriptions below and will become more apparent by embodiments of the disclosure. In addition, the aspects and advantages of the disclosure will be realized through means and combinations thereof in the claims.

According to an embodiment of the disclosure, a display device includes a display panel including a display area, a pad area located on one side of the display area, and a bending area between the display area and the pad area, and an input detection layer on the display panel, wherein the input detection layer includes a plurality of detection electrodes arranged in the display area, detection signal lines extending to the pad area across the bending area and having one ends respectively connected to the plurality of detection electrodes, an insulating layer located at least in the bending area and the pad area and covering at least a portion of the detection signal lines, and a step compensation layer located at least on the insulating layer in the bending area, the insulating layer includes a first groove extending parallel to a bending axis of the display panel and disposed outside the step compensation layer.

In an embodiment, the detection signal lines may each include a first conductive layer and a second conductive layer arranged on the first conductive layer, and the display device may further include a light-blocking layer arranged between the second conductive layer and the insulating layer in the pad area, and covering at least an area where the first groove and the detection signal lines intersect.

In an embodiment, the display device may further include an adhesive layer arranged between the light-blocking layer and the second conductive layer.

In an embodiment, the display device may further include at least one color filter layer arranged between the light-blocking layer and the insulating layer.

In an embodiment, another end of each of the detection signal lines may be connected to an integrated circuit arranged in the pad area.

In an embodiment, the display device may further include a circuit cover covering the integrated circuit.

In an embodiment, the first groove includes a plurality of first grooves spaced apart and extending parallel to each other.

In an embodiment, the insulating layer may covers an area between the bending area and the display area, and include a second groove located opposite to the first groove based on the bending axis.

In an embodiment, the step compensation layer may be located between the first groove and the second groove.

In an embodiment, the plurality of detection electrodes may include first detection electrodes and second detection electrodes arranged in directions perpendicular to each other.

According to another embodiment of the disclosure, a display device includes a substrate including a display area, a pad area located on one side of the display area, and a bending area between the display area and the pad area, a pixel circuit layer including at least one thin-film transistor located on the substrate in the display area, a display element layer arranged on the pixel circuit layer and including an organic light-emitting element electrically connected to at least one thin-film transistor, a thin-film encapsulation layer covering the display element layer, and an input detection layer located on the thin-film encapsulation layer and including detection electrodes, detection signal lines connected to the detecting electrodes and extending from the detection electrodes to the pad area across the bending area, respectively, an insulating layer located on the detection signal lines, and the insulating layer includes a first groove arranged parallel to a bending axis of the bending area and disposed on one side of the bending area, and a second groove arranged parallel to the bending axis of the bending area and disposed on another side of the bending area.

In an embodiment, a step compensation layer may be located on the insulating layer arranged between the first groove and the second groove.

In an embodiment, the first groove and the second groove may limit a formation location of the step compensation layer.

In an embodiment, the first groove includes a plurality of first grooves spaced apart and extending parallel to each other.

In an embodiment, the detection signal lines may each include a first conductive layer and a second conductive layer arranged on the first conductive layer.

In an embodiment, the first conductive layer may include a bridge electrode.

In an embodiment, the second conductive layer may include first detection electrodes and second detection electrodes arranged in directions perpendicular to each other.

In an embodiment, the display device may further include a light-blocking layer arranged between the second conductive layer and the insulating layer in the pad area, and covering at least an area where the first groove and the detection signal lines intersect.

In an embodiment, the display device may further include an adhesive layer arranged between the light-blocking layer and the second conductive layer.

In an embodiment, the display device may further include at least one color filter layer between the light-blocking layer and the insulating layer.

According to another embodiment of the disclosure, an electronic device includes a memory storing at least one program, a processor configured to operate by executing the at least one program, a display device configured to receive data from the processor and provide visual information, and a power module configured to supply power to the display device, wherein the display device includes a display panel including a display area, a pad area located on one side of the display area, and a bending area between the display area and the pad area, and an input detection layer on the display panel, wherein the input detection layer includes a plurality of detection electrodes arranged in the display area, detection signal lines connected to the plurality of detection electrodes and extending from the detection electrodes to the pad area across the bending area, respectively, an insulating layer located at least in the bending area and the pad area and covering at least a portion of the detection signal lines, and a step compensation layer located at least on the insulating layer in the bending area, the insulating layer includes a first groove arranged parallel to a bending axis of the display panel and disposed outside the step compensation layer.

In an embodiment, each of the detection signal lines may include a first conductive layer and a second conductive layer arranged on the first conductive layer, and the display device may further include a light-blocking layer arranged between the second conductive layer and the insulating layer in the pad area, and covering at least an area where the first groove and the detection signal lines intersect.

In an embodiment, the display device may further include an adhesive layer arranged between the light-blocking layer and the second conductive layer.

In an embodiment, the display device may further include at least one color filter layer between the light-blocking layer and the insulating layer.

### BRIEF DESCRIPTION OF THE DRAWINGS

The above and other aspects, features, and advantages of certain embodiments of the disclosure will be more apparent from the following description taken in conjunction with the accompanying drawings in which:

FIG. 1 is a plan view schematically showing a display device according to an embodiment of the disclosure;

FIG. 2 is a perspective view schematically showing a bent shape of the display device of FIG. 1;

FIG. 3 is a block diagram schematically showing a structure of the display device of FIG. 1;

FIG. 4 is a circuit diagram showing an equivalent circuit of one sub-pixel of the display device of FIG. 1 according to an embodiment;

FIG. 5 is a schematic cross-sectional view taken along line A-A′ of FIG. 1 according to an embodiment;

FIG. 6 is a schematic cross-sectional view taken along line D-D′ of FIG. 1 according to an embodiment;

FIG. 7 is a plan view schematically showing an input detection layer of FIG. 6 according to an embodiment;

FIG. 8 is a schematic cross-sectional view taken along line IV-IV′ of FIG. 7 according to an embodiment;

FIG. 9 is a plan view showing a first conductive layer of FIG. 8;

FIG. 10 is an enlarged view schematically showing a region B of FIG. 1 according to an embodiment;

FIG. 11 is a schematic cross-sectional view taken along line C-C′ of FIG. 10 according to an embodiment;

FIG. 12 is a schematic cross-sectional view taken along line C-C′ of FIG. 10, according to another embodiment;

FIG. 13 is a schematic cross-sectional view taken along line E-E′ of FIG. 1 according to an embodiment;

FIG. 14 is a block diagram of an electronic device according to an embodiment; and

FIG. 15 is schematic diagrams of electronic devices according to various embodiments.

### DETAILED DESCRIPTION

The disclosure may have various modifications and various embodiments, and specific embodiments are illustrated in the drawings and are described in detail in the detailed description. Effects and features of the disclosure and methods of achieving the same will become apparent with reference to embodiments described in detail with reference to the drawings. However, the disclosure is not limited to the embodiments described below, and may be implemented in various forms.

In the following embodiments, the terms “first” and “second” are not used in a limited sense and are used to distinguish one component from another component.

In the following embodiments, an expression used in the singular encompasses the expression of the plural, unless it has a clearly different meaning in the context.

In the following embodiments, it will be further understood that the terms “comprise” and/or “comprising” used herein specify the presence of stated features or components, but do not preclude the presence or addition of one or more other features or components.

It will be understood that when a layer, region, or element is referred to as being “formed on” another layer, area, or element, it may be directly or indirectly formed on the other layer, region, or element. That is, for example, intervening layers, regions, or elements may be present.

In the drawings, for convenience of description, sizes of components may be exaggerated or reduced. For example, because sizes and thicknesses of components in the drawings are arbitrarily illustrated for convenience of explanation, the disclosure is not necessarily limited thereto.

Hereinafter, embodiments will be described in detail with reference to the accompanying drawings, and in the following description with reference to the drawings, like reference numerals refer to like elements.

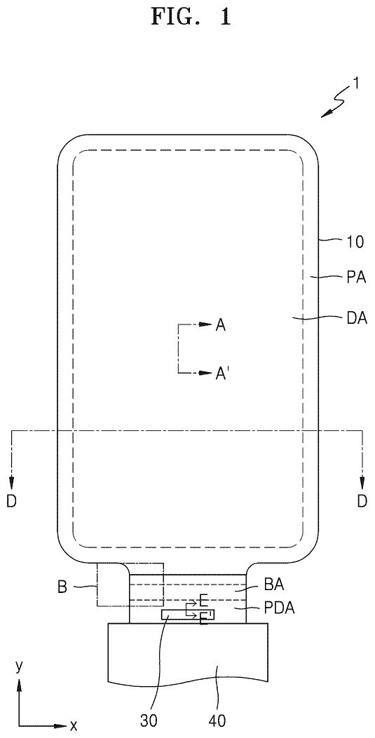

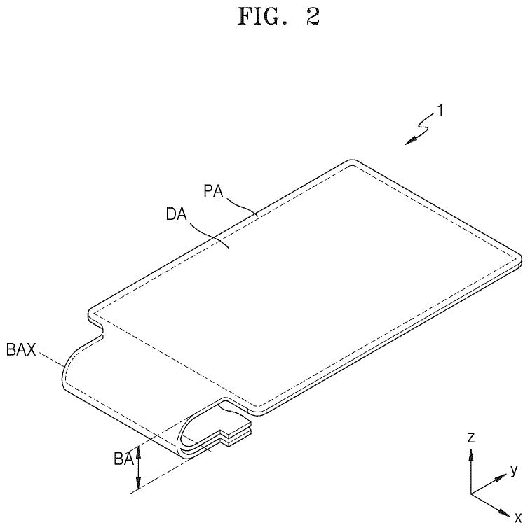

FIG. 1 is a plan view schematically showing a display device 1 according to an embodiment of the disclosure, and FIG. 2 is a perspective view schematically showing a bent shape of the display device 1 of FIG. 1.

Referring to FIGS. 1 and 2, the display device 1 is a device for displaying a moving image or still image and may display an image on a display panel 10 or perform input and output of data. The display device 1 may be used as a display screen of not only a portable electronic device, such as a mobile phone, a smartphone, a tablet personal computer (PC), a mobile communication terminal, an electronic notebook, an electronic book, a portable multimedia player (PMP), a navigation device, or an ultra-mobile PC (UMPC), but also any one of various electronic devices, such as a television, a laptop computer, a monitor, a billboard, and an Internet of things (IoT) device. The display device 1 according to an embodiment may be used for an electronic device such as a wearable device including a smart watch, a watch phone, a glasses-type display, or a head mounted display (HMD). The display device 1 according to an embodiment may be used as a display of any one of various electronic devices, for example, a dashboard of a vehicle, a center information display on a center fascia or dashboard of a vehicle, a room mirror display replacing a side mirror of a vehicle, or a display on the back of a front seat as entertainment for a rear seat of a vehicle.

The display device 1 according to an embodiment of the disclosure may include a display area DA in which a plurality of pixels are arranged, and a peripheral area PA located outside the display area DA. The peripheral area PA may include a pad area PDA that is an area located on one side of the display area DA and where various electronic components, such as an integrated circuit 30, or a flexible circuit board 40 are electrically attached, and a bending area BA between the display area DA and the pad area PDA. The display area DA, the peripheral area PA, the pad area PDA, and the bending area BA may be defined on a substrate.

FIG. 1 is a plan view showing shapes of the substrate and the like during a manufacturing process of the display device 1, and the substrate and the like may have the bending area BA bent along a bending axis BAX extending in a first direction x, as shown in FIG. 2. Here, a bending direction is set so that the pad area PDA is located behind the display area DA. Accordingly, the area of the peripheral area PA perceived by a user may be reduced.

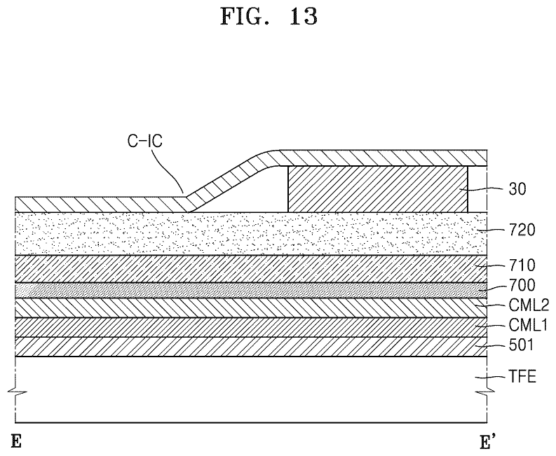

A circuit cover C-IC of FIG. 13 may be attached to the integrated circuit 30 and flexible circuit board 40 of the pad area PDA. The circuit cover C-IC may protect the integrated circuit 30 and the flexible circuit board 40 from a mechanical impact and add waterproofing and insulation performances to the integrated circuit 30 and the flexible circuit board 40.

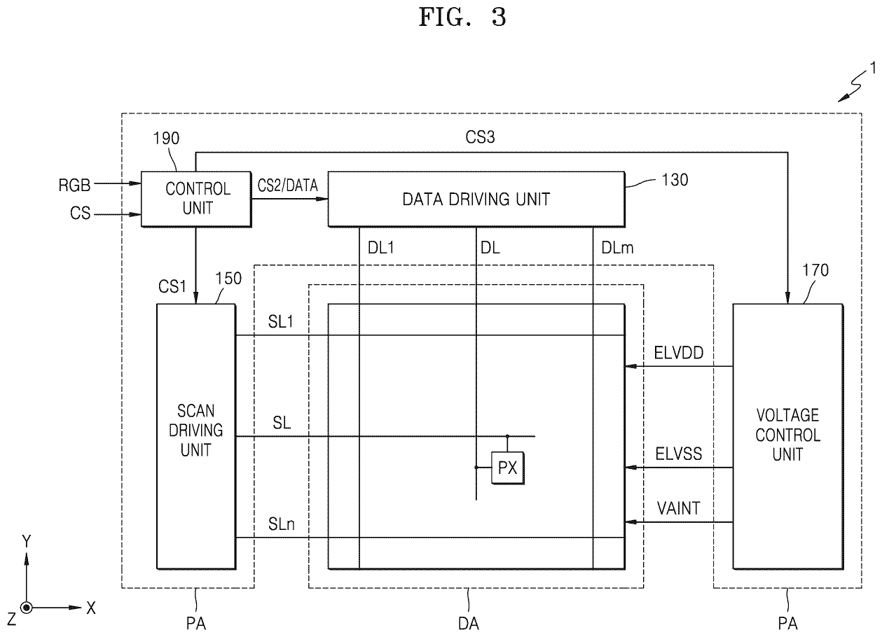

FIG. 3 is a block diagram schematically showing a structure of the display device 1 of FIG. 1.

Referring to FIG. 3, a plurality of scan lines SL1 to SLn extending along the first direction x, a plurality of data lines DL1 to DLm extending along a second direction y perpendicular to the first direction x, and a plurality of sub-pixels PX may be arranged in the display area DA. Here, n and m are each a natural number.

Wires capable of applying electrical signals to the plurality of sub-pixels PX may include the plurality of scan lines SL1 to SLn and the plurality of data lines DL1 to DLm. The plurality of scan lines SL1 to SLn may be, for example, arranged in a plurality of rows extending in the first direction x to transmit scan signals to sub-pixels PX, and the plurality of data lines DL1 to DLm may be, for example, arranged in a plurality of columns extending in the second direction y to transmit data signals to the sub-pixels PX, and the plurality of sub-pixels PX may be positioned at intersections of the plurality of scan lines SL1 to SLn and the plurality of data lines DL1 to DLm.

Each sub-pixel PX may include a light-emitting element to emit red, green, blue, or white light. For example, each sub-pixel PX may include, but is not limited to, an organic light-emitting diode OLED as a light-emitting element.

In the peripheral area PA, a data driving unit 130 configured to provide the data signals to the display area DA, a scan driving unit 150 configured to provide the scan signals to the display area DA, a voltage control unit 170 configured to control voltages supplied to the display area DA, and a control unit 190 configured to control the data driving unit 130, the scan driving unit 150, and the voltage control unit 170 may be arranged.

The voltage control unit 170 may generate and control a first voltage ELVDD, a second voltage ELVSS, and an initialization voltage VAINT provided to the display area DA.

The first voltage ELVDD, the second voltage ELVSS, and the initialization voltage VAINT may be applied to the plurality of sub-pixels PX. For example, the first voltage ELVDD may be a positive voltage, and the second voltage ELVSS may be a negative voltage or a ground voltage. In other words, the second voltage ELVSS may have a lower level than the first voltage ELVDD.

The control unit 190 may receive image signals RGB and a control signal CS from an external source (e.g., a system board). The control unit 190 may generate pieces of image data DATA by converting data formats of the image signals RGB to match an interface specification of the data driving unit 130. The control unit 190 may provide the pieces of image data DATA with the converted data formats to the data driving unit 130.

The control unit 190 may generate and output a first control signal CS1, a second control signal CS2 and a third control signal CS3 in response to the control signal CS provided from an external source. The first control signal CS1 may be defined as a scan control signal, the second control signal CS2 may be defined as a data control signal and the third control signal CS3 may be defined as a voltage control signal. The first control signal CS1 may be provided to the scan driving unit 150. The second control signal CS2 may be provided to the data driving unit 130. The third control signal CSs may be provided to the voltage control unit 170.

The scan driving unit 150 may generate a plurality of scan signals in response to the first control signal CS1. The plurality of scan signals may be applied to the plurality of sub-pixels PX through the plurality of scan lines SL1 to SLn.

The data driving unit 130 may generate a plurality of data voltages corresponding to the pieces of image data DATA in response to the second control signal CS2. The plurality of data voltages may be applied to the plurality of sub-pixels PX through the data lines DL1 to DLm. The da ta driving unit 130 may simultaneously provide, to the data lines DL1 to DLm, the data voltages generated in units of sub-pixel rows in the plurality of sub-pixels PX.

The voltage control unit 170 may generate the first voltage ELVDD, the second voltage ELVSS, and the initialization voltage VAINT in response to the third control signal CS3. The first voltage ELVDD, the second voltage ELVSS, and the initialization voltage VAINT may be applied to the plurality of sub-pixels PX through voltage supply lines.

The plurality of sub-pixels PX may receive the plurality of data voltages in response to the plurality of scan signals. The plurality of sub-pixels PX may display an image by emitting light of luminance corresponding to the plurality of data voltages. The plurality of sub-pixels PX may emit light sequentially or simultaneously to display the image.

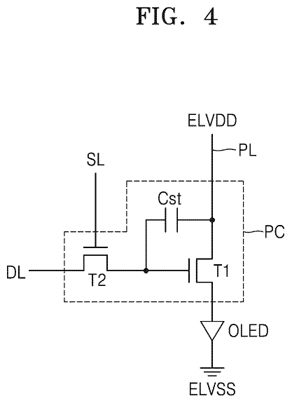

FIG. 4 is a circuit diagram showing an equivalent circuit of one sub-pixel PX of the display device 1 of FIG. 1 according to an embodiment.

Referring to FIG. 4, a pixel circuit PC may be connected to a display element, for example, the organic light-emitting diode OLED. The pixel circuit PC may be arranged in the display area DA. The pixel circuit PC may include a driving thin-film transistor T1, a switching thin-film transistor T2, and a storage capacitor Cst. The organic light-emitting diode OLED may emit red, green, or blue light or may emit red, green, blue, or white light.

The switching thin-film transistor T2 may be connected to a scan line SL and a data line DL, and may transmit, to the driving thin-film transistor T1, a data signal or data voltage input from the data line DL, based on a scan signal or switching voltage input from the scan line SL. The storage capacitor Cst may be connected to a gate electrode of the switching thin-film transistor T2 and a driving voltage line PL, and store a voltage corresponding to a difference between a voltage received from the switching thin-film transistor T2 and the first voltage ELVDD supplied to the driving voltage line PL.

The driving thin-film transistor T1 may be connected to the driving voltage line PL and the storage capacitor Cst, and control a driving current flowing through the organic light-emitting diode OLED from the driving voltage line PL in response to a voltage value stored in the storage capacitor Cst. The organic light-emitting diode OLED may emit light of a certain luminance according to the driving current. An opposing electrode of the organic light-emitting diode OLED may receive the second voltage ELVSS.

In FIG. 4, the pixel circuit PC includes two thin-film transistors and one storage capacitor, but the pixel circuit PC may include 3, 4, 5, or more thin-film transistors and the pixel circuit PC may include 2, 3, or more capacitors.

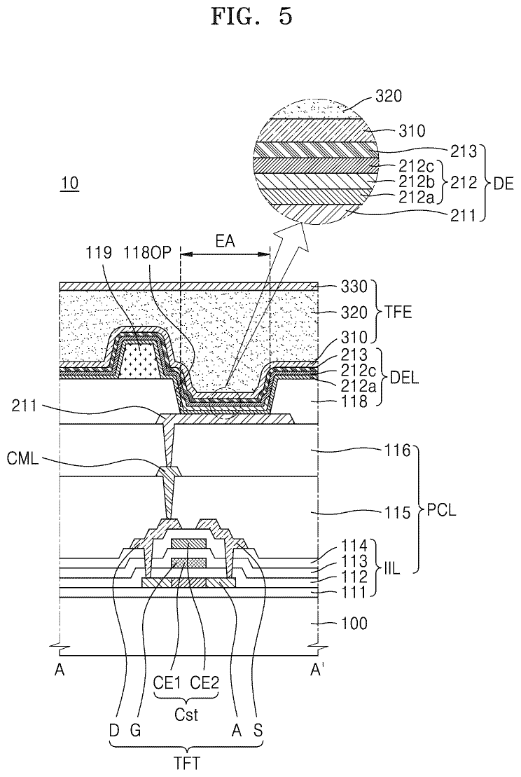

FIG. 5 is a schematic cross-sectional view taken along line A-A′ of FIG. 1 according to an embodiment.

Referring to FIG. 5, the display device 1 may include the display panel 10. The display panel 10 may include a substrate 100, a pixel circuit layer PCL including a buffer layer 111, a display element layer DEL, and a thin-film encapsulation layer TFE.

The substrate 100 may include a transparent glass material containing SiO₂ as a main component. However, the disclosure is not limited thereto, and the substrate 100 may also include a transparent plastic material. Examples of the plastic material may include polyethersulfone (PES), polyacrylate (PAR), polyetherimide (PEI), polyethyelenene napthalate (PEN), polyethyelene terephthalate (PET), polyphenylene sulfide (PPS), polyarylate, polyimide, polycarbonate (PC), cellulose triacetate (TAC), and cellulose acetate propionate (CAP). In an embodiment, the substrate 100 may have a multi-layer structure including a base layer including polymer resin described above and a barrier layer (not shown). The substrate 100 including the polymer resin may be flexible, rollable, or bendable.

The pixel circuit layer PCL may be arranged on the substrate. The pixel circuit layer PCL may include a thin-film transistor TFT included in a pixel circuit, and an inorganic insulating layer IIL, a first planarization layer 115, and a second planarization layer 116, which are arranged below and/or on components of the thin-film transistor TFT. The inorganic insulating layer IIL may include a buffer layer 111, a first gate insulating layer 112, a second gate insulating layer 113, and an interlayer insulating layer 114.

The thin-film transistor TFT may include a semiconductor layer A, and the semiconductor layer A may include polysilicon. Alternatively, the semiconductor layer A may include amorphous silicon, an oxide semiconductor, or an organic semiconductor. The semiconductor layer A may include a channel region and a drain region and a source region which are arranged on opposite sides of the channel region respectively. A gate electrode G may overlap the channel region.

The gate electrode G may include a low-resistance metal material. The gate electrode G may include a conductive material including molybdenum (Mo), aluminum (Al), copper (Cu), or titanium (Ti), and may be formed in a multi-layer or single layer including the conductive material.

The first gate insulating layer 112 between the semiconductor layer A and the gate electrode G may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and/or zinc oxide (ZnOₓ). ZnOₓ may include ZnO and/or ZnO₂.

The second gate insulating layer 113 may be provided to cover the gate electrode G. Like the first gate insulating layer 112, the second gate insulating layer 113 may include an inorganic insulating material, such as SiO₂, SiNₓ, SiON, Al₂O₃, TiO₂, Ta₂O₅, HfO₂, and/or ZnOₓ. ZnOₓ may include ZnO and/or ZnO₂.

An upper electrode CE2 of the storage capacitor Cst may be arranged above the second gate insulating layer 113. The upper electrode CE2 may overlap the gate electrode G disposed therebelow. Here, the upper electrode CE2 and the gate electrode G, which overlap each other with the second gate insulating layer 113 between the upper electrode CE2 and the gate electrode G, may form the storage capacitor Cst of the pixel circuit. In other words, the gate electrode G may operate as a lower electrode CE1 of the storage capacitor Cst. As such, the storage capacitor Cst and the thin-film transistor TFT may overlap each other. However, the disclosure is not limited thereto, and in some embodiments, the storage capacitor Cst may not overlap the thin-film transistor TFT.

The upper electrode CE2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may be a single layer or multi-layer including such a material.

The interlayer insulating layer 114 may cover the upper electrode CE2. The interlayer insulating layer 114 may include SiO₂, SiNₓ, SiON, Al₂O₃, TiO₂, Ta₂O₅, HfO₂, or ZnOₓ. ZnOₓ may include ZnO and/or ZnO₂. The interlayer insulating layer 114 may be a single layer or multi-layer including the inorganic insulating material described above.

A drain electrode D and a source electrode S may each be located on the interlayer insulating layer 114. The drain electrode D and the source electrode S may include a material having good conductivity. The drain electrode D and the source electrode S may include a conductive material including Mo, Al, Cu, or Ti, and may be formed in a multi-layer or single layer including the conductive material. In an embodiment, the drain electrode D and the source electrode S may have a multi-layer structure of Ti/Al/Ti.

The first planarization layer 115 may cover the drain electrode D and the source electrode S. The first planarization layer 115 may include an organic insulating layer. The first planarization layer 115 may include an organic insulating material such as a general-purpose polymer, for example, polymethylmethacrylate (PMMA) or polystyrene (PS), a polymer derivate having a phenol-based group, an acrylic-based polymer, an imide-based polymer, an arylether-based polymer, an amide-based polymer, a fluorine-based polymer, a p-xylene-based polymer, a vinyl alcohol-based polymer, or a blend thereof.

A connection electrode CML may be arranged on the first planarization layer 115. Here, the connection electrode CML may be connected to the drain electrode D or the source electrode S via a contact hole through the first planarization layer 115. The connection electrode CML may include a material having good conductivity. The connection electrode CML may include a conductive material including Mo, Al, Cu, or Ti, and may be formed in a multi-layer or single layer including the conductive material. In an embodiment, the connection electrode CML may have a multi-layer structure of Ti/Al/Ti.

The second planarization layer 116 may cover the connection electrode CML. The second planarization layer 116 may include an organic insulating layer. The second planarization layer 116 may include an organic insulating material such as a general-purpose polymer, for example, polymethylmethacrylate (PMMA) or polystyrene (PS), a polymer derivate having a phenol-based group, an acrylic-based polymer, an imide-based polymer, an arylether-based polymer, an amide-based polymer, a fluorine-based polymer, a p-xylene-based polymer, a vinyl alcohol-based polymer, or a blend thereof.

The display element layer DEL may be arranged on the pixel circuit layer PCL. The display element layer DEL may include a display element DE. The display element DE may include the organic light-emitting diode OLED. A pixel electrode 211 of the display element DE may be electrically connected to the connection electrode CML via a contact hole through the second planarization layer 116.

The pixel electrode 211 may include a conductive oxide, such as indium tin oxide (ITO), indium zinc oxide (IZO), zinc oxide (ZnO), indium oxide (In₂O₃), indium gallium oxide (IGO), or aluminum zinc oxide (AZO). In another embodiment, the pixel electrode 211 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or a compound thereof. In another embodiment, the pixel electrode 211 may further include a layer formed of ITO, IZO, ZnO, or In₂O_{3,} on/below the reflective layer.

A pixel-defining layer 118 including an opening 118OP exposing a center portion of the pixel electrode 211 may be arranged on the pixel electrode 211. The pixel-defining layer 118 may include an organic insulating material and/or an inorganic insulating material. The opening 118OP may define an emission area EA of light emitted from the display element DE. For example, a width of the opening 118OP may correspond to a width of the emission area EA of the display element DE.

In an embodiment, the pixel-defining layer 118 may include a light-blocking material and be provided in black. The light-blocking material may include a resin or paste including carbon black, carbon nanotubes, or black dyes, metal particles such as nickel, aluminum, molybdenum, and an alloy thereof, metal oxide particles (for example, chromium oxide), or metal nitride particles (for example, chromium nitride). When the pixel-defining layer 118 includes the light-blocking material, external light reflection caused by metal structures arranged below the pixel-defining layer 118 may be reduced.

A spacer 119 may be arranged on the pixel-defining layer 118. The spacer 119 may be used to prevent a damage to the substrate 100 during manufacturing the display device 1. A mask sheet may be used while manufacturing the display panel 10, and, at this time, the spacer 119 may prevent the mask sheet from drooping into the opening 118OP of the pixel-defining layer 118 or prevent a portion of the substrate 100 from being damaged or broken by the mask sheet while depositing a deposition material on the substrate 100 close to the pixel-defining layer 118.

The spacer 119 may include an organic insulating material such as polyimide. Alternatively, the spacer 119 may include an inorganic insulating material such as silicon nitride or silicon oxide, or may include an organic insulating material and an inorganic insulating material.

In an embodiment, the spacer 119 may include a material different from the pixel-defining layer 118. In another embodiment, the spacer 119 may include a same material as the pixel-defining layer 118 and, in this case, the pixel-defining layer 118 and the spacer 119 may be formed together using a half-tone mask or the like.

An intermediate layer 212 may be arranged on the pixel-defining layer 118. The intermediate layer 212 may include an emission layer 212b arranged at the opening 118OP of the pixel-defining layer 118. The emission layer 212b may include a high-molecular weight organic material or low-molecular weight organic material which emit light of a certain color.

A first functional layer 212a and a second functional layer 212c may be respectively arranged below and on the emission layer 212b. The first functional layer 212a may include, for example, a hole transport layer (HTL) or may include an HTL and a hole injection layer (HIL). Th second functional layer 212c is a component arranged on the emission layer 212b and may be optional. The second functional layer 212c may include an electron transport layer (ETL) and/or an electron injection layer (EIL). Like an opposing electrode 213 described below, the first functional layer 212a and/or the second functional layer 212c may be a common layer formed to entirely cover the substrate 100.

The opposing electrode 213 may include a conductive material with a low work function. For example, the opposing electrode 213 may include a (semi-)transparent layer including Ag, Mg, Al, Pt, Pd, Au, Ni, Nd, Ir, Cr, lithium (Li), calcium (Ca), or an alloy thereof. Alternatively, the opposing electrode 213 may further include a layer including ITO, IZO, ZnO, or In₂O_{3,} on the (semi-)transparent layer including the above material.

In some embodiments, a capping layer (not shown) may be further arranged on the opposing electrode 213. The capping layer may include lithium fluoride (LiF), an inorganic material, and/or an organic material.

The thin-film encapsulation layer TFE may be arranged on the opposing electrode 213. In an embodiment, the thin-film encapsulation layer TFE may include at least one inorganic encapsulation layer and at least one organic encapsulation layer. For example, the thin-film encapsulation layer TFE may include a first inorganic encapsulation layer 310, an organic encapsulation layer 320, and a second inorganic encapsulation layer 330 which are sequentially stacked on each other.

The first inorganic encapsulation layer 310 and second inorganic encapsulation layer 330 may include one or more inorganic materials from among aluminum oxide, titanium oxide, tantalum oxide, hafnium oxide, zinc oxide, silicon oxide, silicon nitride, and silicon oxynitride. The organic encapsulation layer 320 may include a polymer-based material. Examples of the polymer-based material may include an acrylic resin, an epoxy resin, polyimide, and polyethylene. In an embodiment, the organic encapsulation layer 320 may include acrylate.

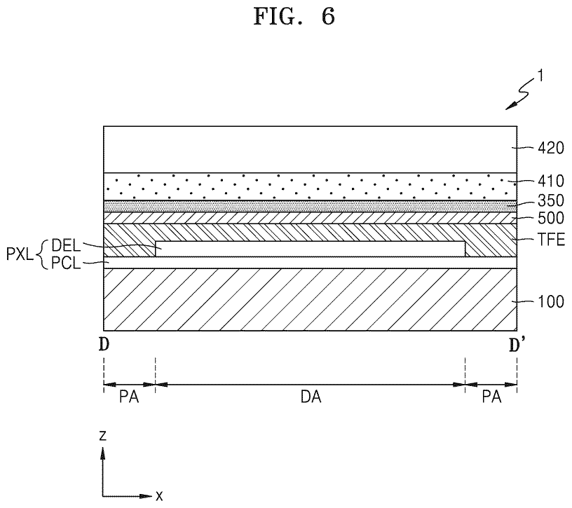

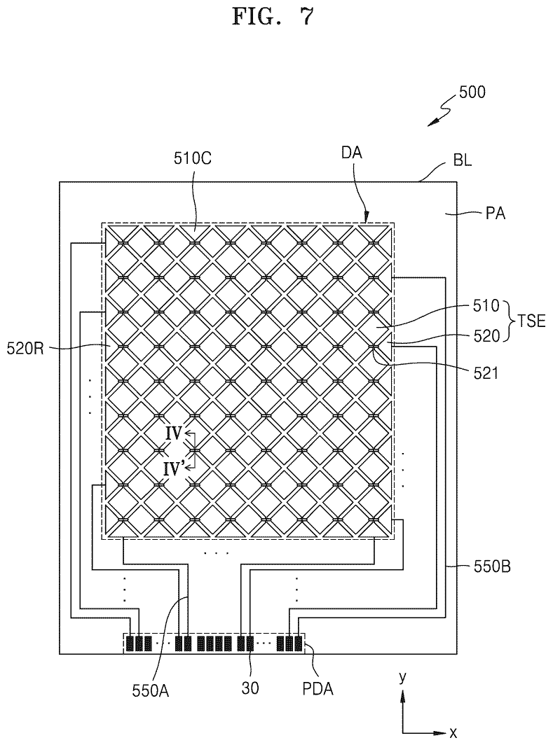

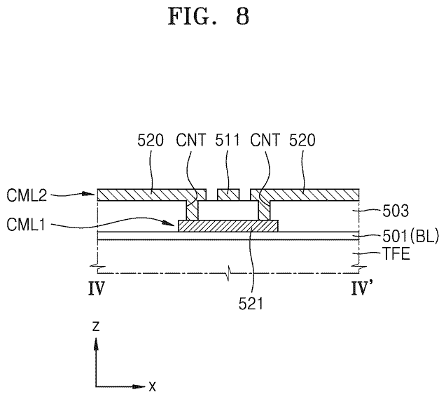

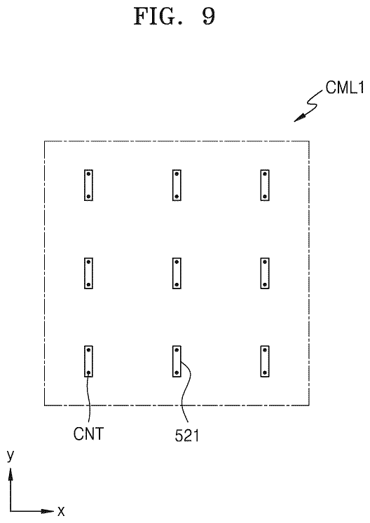

FIG. 6 is a schematic cross-sectional view taken along line D-D′ of FIG. 1 according to an embodiment, FIG. 7 is a plan view schematically showing an input detection layer 500 of FIG. 6 according to an embodiment, FIG. 8 is a schematic cross-sectional view taken along line IV-IV′ of FIG. 7 according to an embodiment, and FIG. 9 is a plan view showing a first conductive layer CML1 of FIG. 8.

Referring to FIG. 6, the display device 1 may include the substrate 100, a pixel layer PXL on the substrate 100, the thin-film encapsulation layer TFE sealing the pixel layer PXL, the input detection layer 500 on the thin-film encapsulation layer TFE, a light control layer 350 on the input detection layer 500, a bonding layer 410 on the light control layer 350, and a functional layer 420 on the bonding layer 410 which are sequentially stacked in a thickness direction (a z direction).

For example, the pixel layer PXL may be arranged on the substrate 100. The pixel layer PXL may include the display element layer DEL including display elements arranged for each pixel and the pixel circuit layer PCL including a pixel circuit and insulating layers arranged for each pixel. The display element layer DEL may be arranged on the pixel circuit layer PCL, and a plurality of insulating layers may be arranged between the pixel circuit and the display element. Some wires and insulating layers of the pixel circuit layer PCL may extend up to the peripheral area PA.

The thin-film encapsulation layer TFE may include at least one inorganic encapsulation layer and at least one organic encapsulation layer. When the display device 1 includes the substrate 100 including a polymer resin and the thin-film encapsulation layer TFE including the inorganic encapsulation layer and the organic encapsulation layer, flexibility of the display device 1 may be improved.

The input detection layer 500 detecting an external input may be arranged on the thin-film encapsulation layer TFE. This will be described later.

The light control layer 350 on the input detection layer 500 may control a path of light emitted from the display element of the display element layer DEL, and may improve a light emission efficiency of the display device 1. As described below, the light control layer 350 may change, together with the bonding layer 410, the path of light emitted from the display element to increase a light extraction efficiency of the display device 1.

The bonding layer 410 may bond the functional layer 420 on the thin-film encapsulation layer TFE to a layer below, for example, the light control layer 350. The bonding layer 410 may improve the light extraction efficiency of the display device 1 by having a higher refractive index than the light control layer 350.

The functional layer 420 may include a polarizing layer. The polarizing layer may transmit only light vibrating in a same direction as a polarization axis among light emitted from the display element of the display element layer DEL, and absorb or reflect light vibrating in other directions. The functional layer 420 may further include an optical film, window, and the like for reflecting external light.

Referring to FIGS. 7 to 9, the input detection layer 500 may include at least a base layer BL located in the display area DA and the peripheral area PA. The base layer BL may correspond to a shape of the substrate 100 and may be provided with a shape substantially identical to that of the substrate 100. In an embodiment, the base layer BL may be a portion of the thin-film encapsulation layer TFE of FIG. 6, for example, the second inorganic encapsulation layer 330 (see FIG. 5) arranged on a top of the thin-film encapsulation layer TFE. In another embodiment, the base layer BL may be an insulating substrate or insulating film including an insulating material such as glass, polymer resin, or the like, separate from the thin-film encapsulation layer TFE.

A plurality of detection electrodes TSE may be arranged in the display area DA. Detection signal lines connected to the detection electrodes TSE may be arranged in the peripheral area PA. The detection electrodes TSE may include a first detection electrode 510 and a second detection electrode 520. The detection signal lines may include a first detection signal line 550A and a second detection signal line 550B. In other words, the input detection layer 500 may include the first detection electrodes 510, the first detection signal lines 550A connected to the first detection electrodes 510, the second detection electrodes 520, and the second detection signal lines 550B connected to the second detection electrodes 520. The input detection layer 500 may be configured to detect an external input through a mutual capacitance method and/or a self-capacitance method.

The input detection layer 500 may include a plurality of conductive layers. Referring to FIG. 8, the input detection layer 500 may include the first conductive layer CML1 and a second conductive layer CML2. A first insulating layer 501, as the base layer BL, may be arranged between the first conductive layer CML1 and the thin-film encapsulation layer TFE, and a second insulating layer 503 may be arranged between the first conductive layer CML1 and the second conductive layer CML2.

In an embodiment, the first and second insulating layers 501 and 503 may be inorganic insulating layers such as silicon nitride. In another embodiment, the first insulating layer 501 may be omitted and the first conductive layer CML1 may be arranged directly on the thin-film encapsulation layer TFE. In another embodiment, the first and second insulating layers 501 and 503 may be organic insulating layers.

The first conductive layer CML1 may include bridge electrodes 521, as shown in FIGS. 7-9. As shown in FIG. 8, the second conductive layer CML2 may include the first detection electrode 510, the second detection electrode 520, and a connecting electrode 511. The first and second conductive layers CML1 and CML2 may include a metal. For example, the first and second conductive layers CML1 and CML2 may include Mo, Al, Cu, or Ti, and may be formed in a multi-layer or single layer including such a material. In an embodiment, the first and second conductive layers CML1 and CML2 may include a multi-layer of Ti/Al/Ti.

The second detection electrodes 520 may be connected to each other by the bridge electrodes 521 provided in a different layer from the second detection electrodes 520. The bridge electrode 521 that electrically connects the neighboring second detection electrodes 520 to each other may be connected to the neighboring second detection electrodes 520 through a contact hole CNT included in the second insulating layer 503. The first detection electrodes 510 may be connected to each other by the connecting electrodes 511 provided in a same layer as the first detection electrodes 510.

FIGS. 8 and 9 illustrate an example in which the bridge electrode 521 is arranged below the first detection electrode 510 and the second detection electrode 520, but the disclosure is not limited thereto, and the first conductive layer CML1 may include the first detection electrode 510 and the second detection electrode 520, and the second conductive layer CML2 may include the bridge electrode 521.

The first detection electrodes 510 may be arranged along a second direction (a y direction), and the second detection electrodes 520 may be arranged along a first direction (an x direction) intersecting the second direction (the y direction). The first detection electrodes 510 may be connected to each other by the connecting electrode 511 between the neighboring first detection electrodes 510 and may form a first detection line 510C. The second detection electrodes 520 arranged along the first direction (the x direction) may be connected to each other by the bridge electrode 521 between the neighboring second detection electrodes 520 and may form a second detection line 520R. The first detection lines 510C and the second detection lines 520R may intersect each other. For example, the first detection lines 510C and the second detection lines 520R may be perpendicular to each other.

The first detection lines 510C and the second detection lines 520R may be arranged in the display area DA, and may be connected to the integrated circuit 30 disposed in the peripheral area PA through the first detection signal lines 550A and the second detection signal lines 550B provided in the peripheral area PA. The first detection lines 510C may be connected to the first detection signal lines 550A, respectively, and the second detection lines 520R may be connected to the second detection signal lines 550B, respectively.

Referring to FIG. 7, the first detection electrodes 510 and the second detection electrodes 520 may have an approximately rhombus shape. The first detection electrode 510 may include lattice lines forming a grid structure (or a lattice structure). Similarly, the second detection electrode 520 may include lattice lines forming a grid structure (or a lattice structure). Here, a line width of each lattice line may be several micrometers.

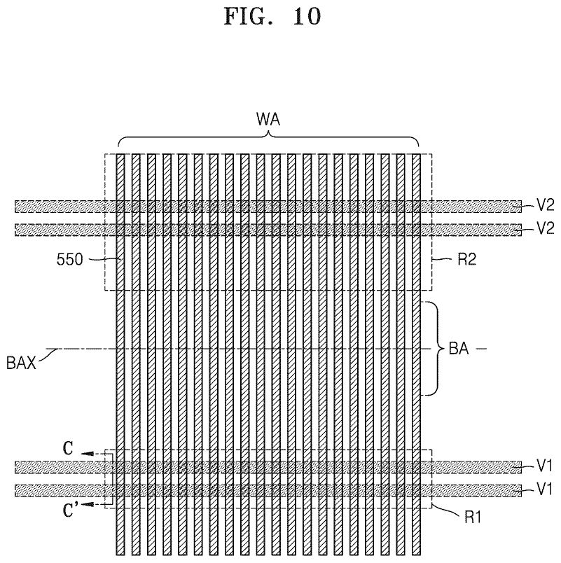

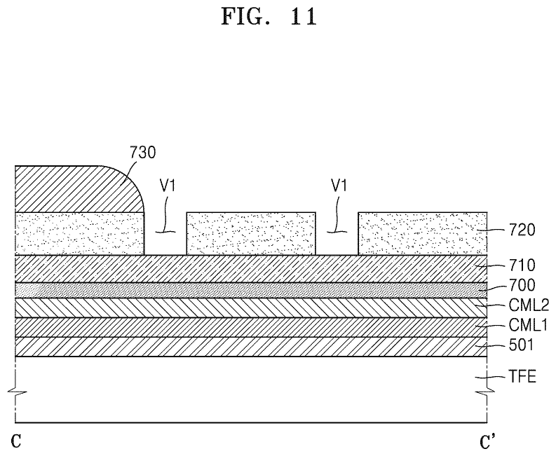

FIG. 10 is an enlarged view schematically showing a region B of FIG. 1 according to an embodiment, and FIG. 11 is a schematic cross-sectional view taken along line C-C′ of FIG. 10, according to an embodiment.

Referring to FIGS. 10 and 11 together with FIG. 1, The display device 1 according to an embodiment of the disclosure may include the display panel 10 including the display area DA, the pad area PDA located on one side of the display area DA, and the bending area BA between the display area DA and the pad area PDA, and the input detection layer 500 on the display panel 10.

The input detection layer 500 may include the plurality of detection electrodes TSE of FIG. 7 arranged in the display area DA on thin-film encapsulation layer TFE, detection signal lines 550 having one ends respectively connected to the plurality of detection electrodes TSE and extending across the bending area BA to the pad area PDA, an insulating layer 720 arranged on at least the bending area BA and the pad area PDA and covering at least some of the detection signal lines 550, and a step compensation layer 730 arranged on the insulating layer 720 at least in the bending area BA. The detection signal lines 550 may each include the first conductive layer CML1 and the second conductive layer CML2 arranged on the first conductive layer CML1.

The detection electrodes TSE arranged in the display area DA may detect external inputs through a mutual capacitance method and/or a self-capacitance method, as described above. The second conductive layer CML2 may include the detection electrodes TSE, and the first conductive layer CML1 may include the bridge electrode 521 of FIG. 8. However, the disclosure is not limited thereto, and the second conductive layer CML2 may include the bridge electrode and the first conductive layer CML1 may include the detection electrodes TSE.

The detection electrodes TSE and the bridge electrodes 521 may be respectively connected to the second conductive layer CML2 and the first conductive layer CML1 of the detection signal lines 550 extending from the peripheral area PA across the bending area BA to the pad area PDA. The detection signal lines 550 may be connected to the integrated circuit 30 arranged in the pad area PDA. In other words, one ends of the detection signal lines 550 may be connected to the detection electrodes TSE and the bridge electrode 521 arranged in the display area DA, and the other ends of the detection signal lines 550 may be connected to the integrated circuit 30 arranged in the pad area PDA.

The insulating layer 720 that insulates the detection signal lines 550 may be arranged on the detection signal lines 550, and the step compensation layer 730 that prevents a step difference occurring in the bending area BA may be arranged on the insulating layer 720.

The step compensation layer 730 may be formed on the insulating layer 720 in the bending area BA and the periphery of the bending area BA by, for example, a laser jetting or laser soldering method. In order to control a location of the step compensation layer 730, the insulating layer 720 may include a first groove V1 arranged parallel to the bending axis BAX of the bending area BA below the bending area BA and a second groove V2 arranged parallel to the bending axis BAX of the bending area BA above the bending area BA.

Here, “below the bending area BA” may indicate an area where the integrated circuit 30 of the pad area PDA is arranged at a boundary between the bending area BA and the pad area PDA. Also, “above the bending area BA” may indicate an area extending from the boundary between the bending area BA and the peripheral area PA to the display area DA.

The insulating layer 720 and the step compensation layer 730 may be organic layers including organic materials. For example, the insulating layer 720 and the step compensation layer 730 may include a material that adhere well to each other. In another example, after forming an adhesive layer on the insulating layer 720, the step compensation layer 730 may be formed on the adhesive layer. In another example, an upper surface of the insulating layer 720 (where the step compensation layer 730 is arranged) may be surface-treated to be hydrophobic to increase adhesion to the step compensation layer 730, and then the step compensation layer 730 may be formed on the insulating layer 720.

As such, when the insulating layer 720 includes the first groove V1 arranged parallel to the bending axis BAX of the bending area BA below the bending area BA and the second groove V2 arranged parallel to the bending axis BAX of the bending area BA above the bending area BA, the step compensation layer 730 may be formed on the insulating layer 720 between the first groove V1 and the second groove V2 of the insulating layer 720 when the step compensation layer 730 is formed on the insulating layer 720. In other words, the first groove V1 and the second groove V2 may limit the formation location of the step compensation layer 730 to be limited between the first groove V1 and the second groove V2 of the insulating layer 720. Accordingly, an efficiency of a manufacturing process of the display device 1 may be improved by controlling the formation location of the step compensation layer 730.

Meanwhile, each of the first groove V1 and the second groove V2, which are parallel to the bending axis BAX of the display panel 10 may be provided as pluralities of first grooves V1 and second grooves V2 while being spaced apart from each other, may have a portion not covered by the step compensation layer 730. Each of the first groove V1 and the second groove V2 may have an area where the step compensation layer 730 is not applied on the insulating layer 720. In FIG. 10, there are two first grooves V1 and two second grooves V2, but the numbers of first grooves V1 and second grooves V2 are not limited thereto and may be one or more.

For example, when the plurality of first grooves V1 are provided, even if the step compensation layer 730 is formed to cover one first groove V1 close to the bending area BA due to tolerance or the like when forming the step compensation layer 730 on the insulating layer 720, another first groove V1 adjacent to the one first groove V1 may restrict formation of the step compensation layer 730.

In other words, when the insulating layer 720 includes the pluralities of first grooves V1 and second grooves V2, the pluralities of first grooves V1 and second grooves V2 may limit the formation location of the step compensation layer 730, thereby further improving precision of a process of forming the step compensation layer 730 on the insulating layer 720.

A light-blocking layer 710 may be further included, which is arranged between the second conductive layer CML2 and the insulating layer 720 in the pad area PDA and covers at least an area intersecting the first groove V1 and the detection signal lines 550. As shown in FIGS. 10 and 11, the light-blocking layer 710 may be arranged between the second conductive layer CML2 and the insulating layer 720 in a first region R1 including locations where the first grooves V1 are arranged and the periphery of the first grooves V1. The light-blocking layer 710 may be arranged between the second conductive layer CML2 and the insulating layer 720 in a second region R2 disposed between the display area DA and the bending area BA to be overlapped with the second grooves V2 and the periphery of the second grooves V2.

When the insulating layer 720 arranged on the detection signal lines 550 includes the first groove V1 and the second groove V2 described above, the first groove V1 and the second groove V 2 may expose the second conductive layer CML2 located on an upper layer of the detection signal lines 550 to an external environment, causing corrosion of the second conductive layer CML2.

In order to prevent corrosion of the detection signal lines 550 in the first region R1 and the second region R2, the second conductive layer CML2 may be omitted and an inorganic layer may be arranged on the second conductive layer CML2 arranged at a location overlapping the first groove V1 and the second grooves V2 to protect the second conductive layer CML2.

However, as described above, when the detection signal lines 550 do not include the first conductive layer CML1 and the second conductive layer CML2 and include a single layer of a conductive layer, resistance of the detection signal lines 550 may increase due to a decrease in the cross-sectional area of the conductive layer of the detection signal lines 550.

However, as in an embodiment of the disclosure, when the light-blocking layer 710 is arranged between the second conductive layer CML2 and the insulating layer 720 in the first region R1 and the second region R2, the light-blocking layer 710 may prevent corrosion of the second conductive layer CML2, and thus, the detection signal lines 550 arranged at locations overlapping the first groove V1 and the second groove V2 may also have a multi-layer structure including the first conductive layer CML1 and the second conductive layer CML2. As a result, the cross-sectional area of the detection signal lines 550 increases and the resistance of the detection signal lines 550 decreases, thereby improving electrical characteristics of the display device 1.

The light-blocking layer 710 may include a black matrix layer covering the periphery of an emission area formed in a sub-pixel of the display element layer DEL of FIG. 6 including the organic light-emitting element. The light-blocking layer 710 may be arranged between the sub-pixels to prevent unnecessary diffusion of light, thereby preventing colors and light between sub-pixels from being mixed with each other and enabling more accurate color expression. The light-blocking layer 710 may include any well-known material of the light-blocking layer 710.

In other words, the light-blocking layer 710 may be arranged in the display area DA and peripheral area PA, and, when the light-blocking layer 710 is formed in the display area DA, a process of forming the light-blocking layer 710 on the insulating layer 720 of the first region R1 and the second region R2 may also be performed. Accordingly, as described above, rather than protecting the detection signal lines 550 from corrosion by using a separate inorganic layer, or the like, a process of covering the detection signal lines 550 with the light-blocking layer 710 may be performed simultaneously when forming the light-blocking layer 710 in the display area DA, thereby simplifying the manufacturing process of the display device 1 and improving a process efficiency.

In addition, in order to prevent waste of materials, the light-blocking layer 710 may be formed on the insulating layer 720 in an area WA disposed between the bending area BA and the display area DA through which the detection signal lines 550 pass to be connected to pads in the pad area PDA.

When materials of the second conductive layer CML2 and the light-blocking layer 710 are different from each other, an adhesive layer 700 may be provided between the second conductive layer CML2 and the light-blocking layer 710 to improve adhesive strength between the light-blocking layer 710 and the second conductive layer CML2.

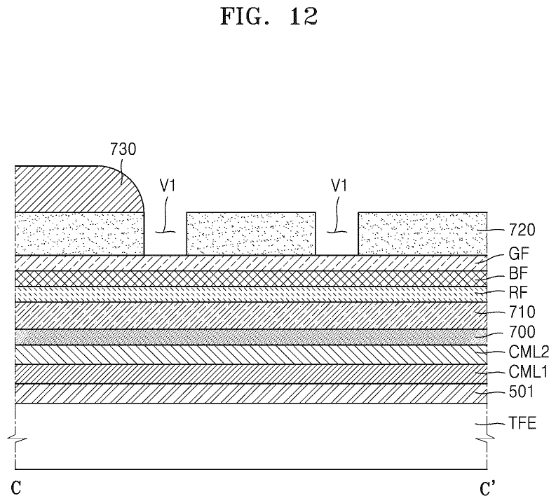

FIG. 12 is a schematic cross-sectional view taken along line C-C′ of FIG. 10 according to another embodiment.

FIG. 12 is identical to FIG. 10 except for color filter layers GF, BF, and RF, and thus, redundant description will be omitted and only added components will be described.

As described above, as shown in FIG. 10, the light-blocking layer 710 may be arranged between the second conductive layer CML2 and the insulating layer 720 in the first region R1 including the locations where the first grooves V1 are arranged and the periphery of the first grooves V1 and in the second region R2 disposed between the display area DA and the bending area BA to be overlapped with the second grooves V2 and the periphery of the second grooves V2.

Referring to FIG. 12, to prepare for a case where the light-blocking layer 710 is consumed or is unable to completely cover the second conductive layer CML2 in an area where the light-blocking layer 710 overlaps grooves due to tolerance, another embodiment of the disclosure may further include at least one of the color filter layers GF, BF, and RF between the light-blocking layer 710 and the insulating layer 720.

The color filter layers GF, BF, and RF may be arranged in an emission area of a sub-pixel to improve color accuracy and a color area of the sub-pixel arranged in the display area DA, When forming the color filter layers GF, BF, and RF in the display area DA, a process of also forming the color filter layers GF, BF, and RF on the insulating layer 720 of the first region R1 and the second region R2 may be performed.

In other words, when forming the color filter layers GF, BF, and RF in the display area DA, a process of covering the detection signal lines 550 with the color filter layers GF, BF, and RF is performed simultaneously, so that the manufacturing process of the display device 1 may be simplified and the process efficiency may be improved.

Although FIG. 12 illustrates that three color filter layers GF, BF, and RF are provided between the light-blocking layer 710 and the insulating layer 720, the disclosure is not limited thereto, and any one or a combination of a red-color filter layer RF, a green-color filter layer GF, and a blue-color filter layer BF may be provided between the light-blocking layer 710 and the insulating layer 720. When the color filter layers GF, BF, and RF are multi-layered, a stacking order is not limited.

FIG. 13 is a schematic cross-sectional view taken along line E-E′ of FIG. 1, according to an embodiment.

Referring to FIG. 13 together with FIG. 1, the circuit cover C-IC may be attached to the integrated circuit 30 and flexible circuit board 40 of the pad area PDA. The circuit cover C-IC may protect the integrated circuit 30 and the flexible circuit board 40 from a mechanical impact and add waterproofing and insulation performances to the integrated circuit 30 and the flexible circuit board 40.

As described above, one ends of the detection signal lines 550 may be connected to the detection electrodes TSE of FIG. 7 and the bridge electrode 521 arranged in the display area DA, and the other ends of the detection signal lines 550 may be connected to the integrated circuit 30 arranged in the pad area PDA.

Here, corrosion or contamination may occur on the circuit cover C-IC attached to the integrated circuit 30 and the flexible circuit board 40, and the corrosion or contamination may spread downward and damage the detection signal lines 550.

Accordingly, the first region R1 of FIG. 10 including the locations where the first grooves V1 are arranged and the periphery of the first grooves V1 may extend to a region where the integrated circuit 30 or the flexible circuit board 40 is arranged. Also, the light-blocking layer 710 may be arranged between the second conductive layer CML2 and the insulating layer 720 in the first region R1. Accordingly, the light-blocking layer 710 may protect the detection signal lines 550 and prevent the detection signal lines 550 from being damaged by the corrosion or contamination of the circuit cover C-IC.

Although not illustrated, at least one of the color filter layers GF, BF, and RF may be arranged between the light-blocking layer 710 and the insulating layer 720 to protect the detection signal lines 550 together with the light-blocking layer 710.

The display device 1 according to embodiments of the disclosure may be applied to any one of various electronic devices 1000. The electronic device 1000 according to an embodiment includes the display device 1 described above, and may further include a module or device having additional functions, in addition to the display device 1.

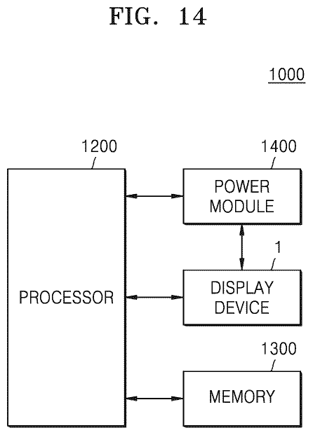

FIG. 14 is a block diagram of the electronic device 1000 according to an embodiment.

Referring to FIG. 14, the electronic device 1000 according to an embodiment may include the display device 1, a processor 1200, a memory 1300, and a power module 1400.

The display device 1 may receive data from the processor 1200 and provide visual information. The display device 1 may be the display device 1 according to the embodiments of the disclosure described above.

The processor 1200 may include at least one of a central processing unit (CPU), an application processor (AP), a graphics processing unit (GPU), a communication processor (CP), an image signal processor (ISP), and a controller. For example, the processor 1200 may operate by executing at least one program.

The memory 1300 may store data information necessary for operations of the processor 1200 or the display device 1. For example, the memory 1300 may store at least one of the programs. When the processor 1200 executes an application stored in the memory 1300, an image data signal and/or an input control signal is transmitted to the display device 1, and the display device 1 may process the received signal and output image information through a display screen.

The power module 1400 may include a power supply module, such as a power adapter or a battery device, and a power conversion module configured to convert power supplied by the power supply module to generate power required for operations of the electronic device 1000. For example, the power module 1400 may supply power to the display device 1.

At least one of the components of the electronic device 1000 may be included in the display device 1 according to the above-described embodiments. Some of the individual modules functionally included in one module may be included in the display device 1 and others may be provided separately from the display device 1.

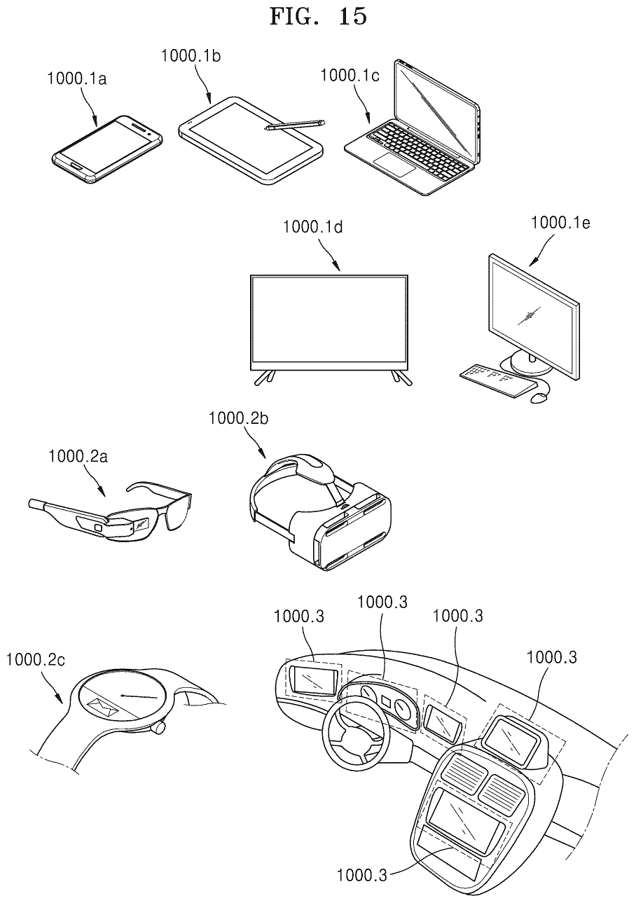

FIG. 15 is schematic diagrams of electronic devices according to various embodiments.

Referring to FIG. 15, various electronic devices to which an display device according to embodiments of the disclosure is applied may include not only image display electronic devices such as a smartphone 1000.1a, a tablet personal computer (PC) 1000.1b, a laptop PC 1000.1c, a television (TV) 1000.1d, and a desktop monitor 1000.1e, but also wearable electronic devices including display devices such as smart glasses 1000.2a, a head mounted display 1000.2b, and a smart watch 1000.2c, and vehicle electronic devices 1000.3 including display devices such as dashboard of a vehicle, a CID arranged on a center facia or dashboard of a vehicle, and a room mirror display.

According to embodiments of the disclosure, an insulating layer covering a detection signal line includes grooves above and below a bending area, and thus, the grooves restrict a formation location of a step compensation layer located on the insulating layer, thereby improving efficiency of manufacturing processes of a display device and an electronic device including the same.

In addition, by arranging a light-blocking layer on the detection signal line arranged below the grooves to prevent corrosion of a second conductive layer of the detection signal line, the detection signal line may be configured in a double layer to reduce resistance of the detection signal lines, thereby improving electrical characteristics of the display device and the electronic device including the same.

However, effects that are obtained through the disclosure are not limited to the effects described above, and other technical effects that not mentioned will be clearly understood by one of ordinary skill in the art from the description of the disclosure.

Embodiments described above may be implemented independently, but it is obvious that a structure of each embodiment may be applied in combination to other embodiments.

The disclosure has been described with reference to the embodiments shown in the drawings, but the embodiments are only examples and it would be understood by one of ordinary skill in the art that various modifications and equivalent embodiments are possible. Accordingly, the scope of the disclosure will be defined by the appended claims.

Certain executions described in an embodiment are embodiments and do not limit the scope of the embodiment in any way. Also, elements described herein may not be essential elements for application of the disclosure unless the elements are particularly described as being “essential” or “critical”.

The term “the” and similar referential terms in the specification (specifically in the claims) of an embodiment may be used for both the singular and the plural.

Further, when a range is described in an embodiment, the disclosure includes inventions to which individual values belonging to the range are applied (unless otherwise stated), and it is considered that each individual value configuring the range is described in the detailed description.

Lastly, unless an order is clearly stated or unless otherwise stated, operations configuring a method according to an embodiment may be performed in an appropriate order. An embodiment is not necessarily limited by an order the operations are described.

In an embodiment, the use of all examples or exemplary terms is merely for describing the embodiment in detail and the scope of the embodiment is not limited by those examples or exemplary terms unless defined in the claims.

Also, it would be obvious to one of ordinary skill in the art that various modifications, combinations, and changes may be made according to design conditions and factors within the scope of claims or equivalents.

What is claimed is:

1. A display device comprising:
a display panel including a display area, a pad area located on one side of the display area, and a bending area between the display area and the pad area; and
an input detection layer on the display panel,
wherein the input detection layer comprises:
a plurality of detection electrodes arranged in the display area;
detection signal lines extending to the pad area across the bending area and having one ends respectively connected to the plurality of detection electrodes;
an insulating layer located at least in the bending area and the pad area and covering at least a portion of the detection signal lines; and
a step compensation layer located at least on the insulating layer in the bending area, and
wherein the insulating layer comprises a first groove extending parallel to a bending axis of the display panel and disposed outside the step compensation layer.

2. The display device of claim 1, wherein the detection signal lines each comprise a first conductive layer and a second conductive layer arranged on the first conductive layer, and
wherein the display device further comprises a light-blocking layer arranged between the second conductive layer and the insulating layer in the pad area, and covering at least an area where the first groove and the detection signal lines intersect.

3. The display device of claim 2, further comprising an adhesive layer arranged between the light-blocking layer and the second conductive layer.

4. The display device of claim 2, further comprising at least one color filter layer arranged between the light-blocking layer and the insulating layer.

5. The display device of claim 2, wherein another end of each of the detection signal lines is connected to an integrated circuit arranged in the pad area.

6. The display device of claim 5, further comprising a circuit cover covering the integrated circuit.

7. The display device of claim 1, wherein the first groove includes a plurality of first grooves spaced apart from and extending parallel to each other.

8. The display device of claim 1, wherein the insulating layer covers an area between the bending area and the display area, and comprises a second groove located opposite to the first groove based on the bending axis.

9. The display device of claim 8, wherein the step compensation layer is located between the first groove and the second groove.

10. A display device comprising:
a substrate including a display area, a pad area located on one side of the display area, and a bending area between the display area and the pad area;
a pixel circuit layer including at least one thin-film transistor located on the substrate in the display area;
a display element layer arranged on the pixel circuit layer and including an organic light-emitting element electrically connected to at least one thin-film transistor;
a thin-film encapsulation layer covering the display element layer;
an input detection layer located on the thin-film encapsulation layer and including detection electrodes,
detection signal lines connected to the detecting electrodes and extending from the detection electrodes to the pad area across the bending area, respectively, and
an insulating layer located on the detection signal lines,
wherein the insulating layer includes a first groove arranged parallel to a bending axis of the bending area and disposed on one side of the bending area, and a second groove arranged parallel to the bending axis of the bending area and disposed on another side of the bending area.

11. The display device of claim 10, wherein a step compensation layer is located on the insulating layer arranged between the first groove and the second groove.

12. The display device of claim 10, wherein the first groove includes a plurality of first grooves spaced apart from and extending parallel to each other.

13. The display device of claim 10, wherein the detection signal lines each comprise a first conductive layer and a second conductive layer arranged on the first conductive layer.

14. The display device of claim 13, further comprising a light-blocking layer arranged between the second conductive layer and the insulating layer in the pad area, and covering at least an area where the first groove and the detection signal lines intersect.

15. The display device of claim 14, further comprising an adhesive layer arranged between the light-blocking layer and the second conductive layer.

16. The display device of claim 14, further comprising at least one color filter layer between the light-blocking layer and the insulating layer.

17. An electronic device comprising:
a memory storing at least one program;
a processor configured to operate by executing the at least one program;
a display device configured to receive data from the processor and provide visual information; and
a power module configured to supply power to the display device,
wherein the display device comprises:
a display panel including a display area, a pad area located on one side of the display area, and a bending area between the display area and the pad area; and
an input detection layer on the display panel,
wherein the input detection layer comprises:
a plurality of detection electrodes arranged in the display area;
detection signal lines connected to the plurality of detection electrodes and extending from the detection electrodes to the pad area across the bending area, respectively;
an insulating layer located at least in the bending area and the pad area and covering at least a portion of the detection signal lines; and
a step compensation layer located at least on the insulating layer in the bending area, and
wherein the insulating layer comprises a first groove arranged parallel to a bending axis of the display panel and disposed outside the step compensation layer.

18. The electronic device of claim 17, wherein each of the detection signal lines comprises a first conductive layer and a second conductive layer arranged on the first conductive layer, and
wherein the display device further comprises a light-blocking layer arranged between the second conductive layer and the insulating layer in the pad area, and covering at least an area where the first groove and the detection signal lines intersect.

19. The electronic device of claim 18, wherein the display device further comprises an adhesive layer arranged between the light-blocking layer and the second conductive layer.

20. The electronic device of claim 18, wherein the display device further comprises at least one color filter layer between the light-blocking layer and the insulating layer.
